(19) United States
(12) Patent Application Publication
(10) Pub. No.: US 2004/0257133 A1
(43) Pub. Date: Dec. 23, 2004

(54) Semiconductor integrated circuit

(75) Inventor: Atsushi Ishikawa, Fujimi-machi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/834,169

(22) Filed: Apr. 29, 2004

(30) Foreign Application Priority Data
May 26, 2003 (JP) 2003-148014

(51) Int. Cl. H03L 7/06

(52) U.S. Cl. 327/172

(57) ABSTRACT

The invention provides a semiconductor integrated circuit incorporating a clock signal multiplying circuit which can generate a double multiplied clock signal in following up changes in power voltage and a frequency of a reference clock signal without using a phase comparator. The semiconductor integrated circuit can include first circuits which delay clock signals in stages, a second circuit which selects one of a plurality of delay clock signals which have been provided with different delays in the first circuits, and a third circuit which generates a double multiplied clock signal with a frequency double the clock signal based on a delay clock signal selected by the clock signals inputted to the first circuits and the second circuit.

### BACKGROUND OF THE INVENTION

1. Field of Invention

This invention relates to a semiconductor integrated circuit incorporating a built-in clock signal multiplying circuit multiplying a frequency of a clock signal.

2. Description of Related Art

In general, a semiconductor integrated circuit handling digital signals has many built-in circuits, such as a flip-flop, operating synchronously with clock signals. A clock signal multiplying circuit may be used to multiply a frequency of a clock signal to be supplied to such a circuit.

The simplest structure to realize a clock signal multiplying circuit for double multiplying the frequency of the clock signal is what delays the clock signal by a gate delay, such as an inverter and a buffer, obtaining an exclusive OR of a clock signal prior to a delay and a clock signal subsequent to a delay. On the other hand, power voltage varies with 3.3V, 2.7V, 1.8V and the like. In a clock signal multiplying circuit designed on an assumption that a single power voltage will be supplied, should the power voltage decrease from a design value, delay time in the gate delay increases, so that a ratio of the delay time to a frequency of a basic clock signal changes. As a result, a follow-up range with respect to the frequency of the basic clock signal changes, thereby causing duty of the double multiplied clock signal to deviate from 50%. There is a problem in that this has made it necessary to reduce the frequency of the basic clock signal, otherwise it would be impossible to double multiply the basic clock signal stably.

Now, in Japanese Published Patent No. 2003-124806 (First page, FIG. 1), there is disclosed a multiplying clock generating circuit which has realized a phase matching in good precision, at the same time, reducing a width of delay adjustment and shortening lock time. According to this multiplying clock generating circuit, in a feedback clock generating circuit, there are generated as many clocks as a multiplying number, having the same frequency as a reference clock and having phase variation such that one phase is variant from another by an equal spacing of 1/ multiplying number, and by feeding back any of the clocks as a feedback clock to a phase comparator, the width of delay adjustment of a delay adjusting circuit is reduced and the lock time is shortened. After locking, by feeding back a quadruple multiplying output clock as the feedback clock, the phase matching in good precision is accomplished. Nonetheless, when generating as a multiplying clock by using the phase comparator, circuit construction becomes complicated.

### SUMMARY OF THE INVENTION

In view of the above-mentioned points, this invention is intended to provide a semiconductor integrated circuit incorporating a clock signal multiplying circuit which can generate double multiplied clock signals following up changes in power voltage and a frequency of a reference clock signal.

To address the problems mentioned above, a semiconductor circuit according to this invention can include a first circuit delaying a clock signal in stages, a second circuit selecting one from a plurality of delay clock signals being provided with different delays in the first circuit, and a third circuit generating a double multiplied clock signal having a frequency double a clock signal based on a clock signal inputted to the first circuit and the delay clock signal selected by the second circuit. The first circuit may be adapted to include a plurality of buffers connected in series. Further, the third circuit may be designed so as to include a circuit generating a double multiplied clock signal having a frequency double the clock signal by obtaining an exclusive OR of the clock signal inputted to the first circuit and the delay clock signal selected by the second circuit.

Additionally, the semiconductor integrated circuit according to this invention may be designed to further include a control circuit controlling the second circuit based on the duty of a double multiplied clock signal generated by the third circuit. This control circuit may also be adapted to include a low-pass filter, which integrates a double multiplied clock signal generated by the third circuit, and a comparator or an AD converter, which compares an output voltage of the low-pass filter with a reference voltage, outputting a comparative result obtained thereby as a control signal. Furthermore, it may be designed such that the second circuit includes a circuit selecting one of a plurality of delay clock signals respectively outputted by a prescribed buffer of a plurality of buffers in accordance with a control signal outputted by the control circuit.

According to this invention, inasmuch as the double multiplied clock signal is generated based on the clock signal inputted to the first circuit and the clock signal selected by the second circuit, without using a phase comparator, even if the power voltage and the frequency of the reference clock signal change, it is possible to generate a double multiplied clock signal by following up such changes.

### BRIEF DESCRIPTION OF THE DRAWINGS

The invention will be described with reference to the accompanying drawings, wherein like numerals reference like elements, and wherein:

FIG. 1 is a diagram showing a clock signal multiplying circuit according to a first embodiment of this invention;

FIG. 2 is a waveform diagram showing operation of the clock signal multiplying circuit shown in FIG. 1;

FIG. 3 is a diagram showing an example of construction of a control circuit shown in FIG. 1;

FIG. 4 is a diagram of a clock signal multiplying circuit according to a second embodiment of this invention; and

FIG. 5 is a waveform diagram of the clock signal multiplying circuit shown in FIG. 4.

### DETAILED DESCRIPTION OF PREFERRED EMBODIMENTS

Preferred embodiments of this invention will be described below with reference to drawings.

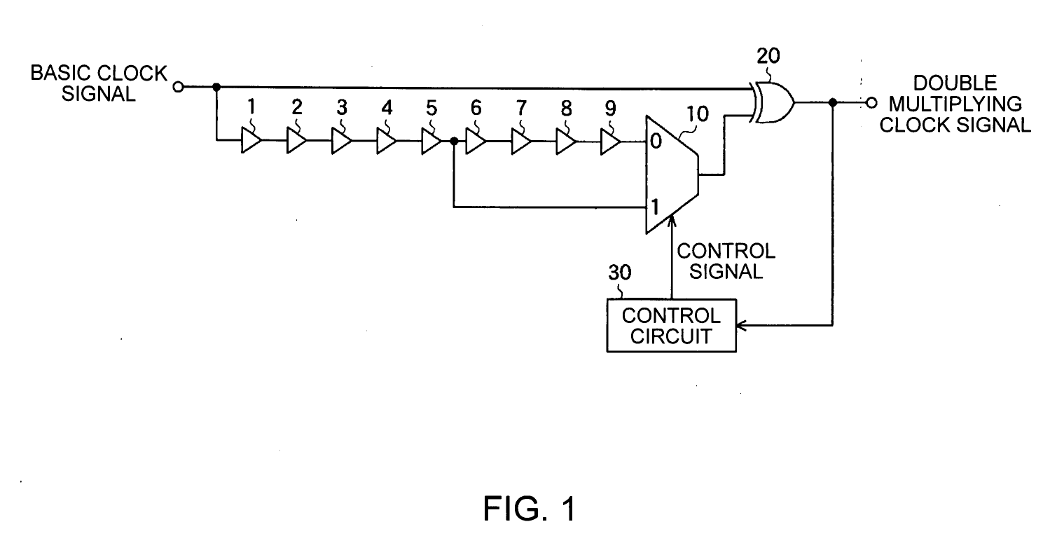

FIG. 1 shows an exemplary construction of a clock signal multiplying circuit included in a semiconductor integrated circuit according to a first embodiment of this invention. As shown in FIG. 1, this clock signal multiplying circuit includes a plurality of buffers 1-9 connected in series to delay an inputted clock signal (hereinafter referred to also as the Basic ClockSignal) in stages, a selector 10 to select one of the delay clock signals of two kinds which have been provided with different delays in these buffers 1-9, an exclusive OR circuit 20 generating double multiplied clock signals having a frequency double the basic clock signal based on the delay clock signal selected by the basic clock signal and the selector 10, and a control circuit 30 controlling the selector 10.

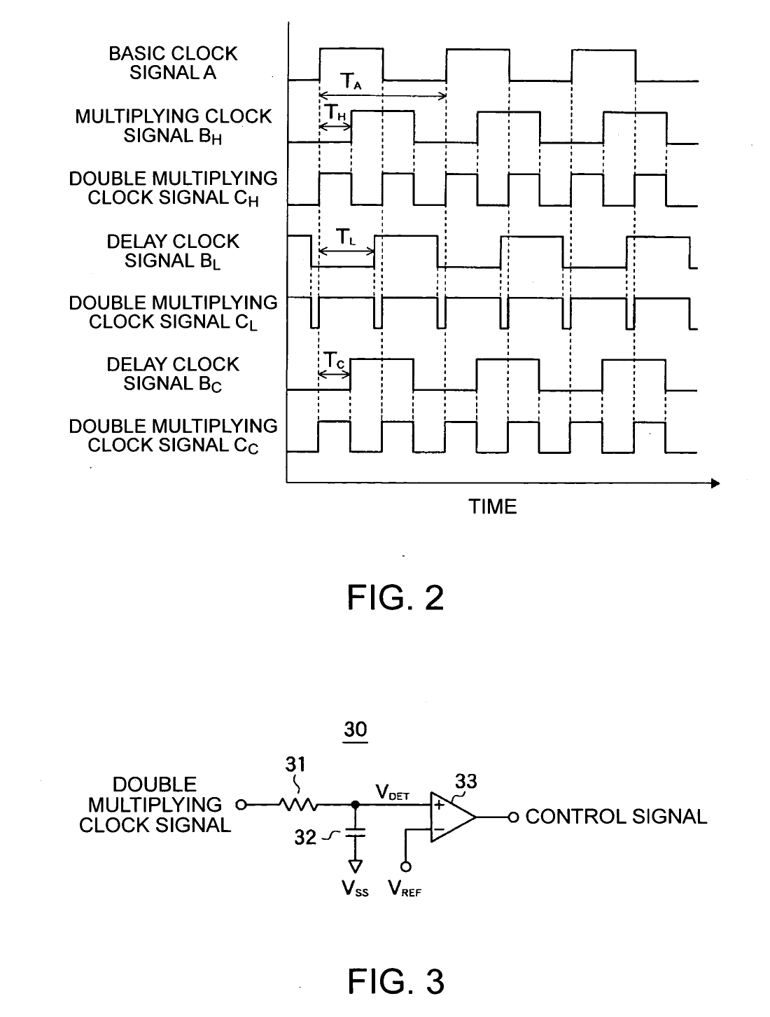

Referring to FIG. 1 and FIG. 2, operation of the clock signal multiplying circuit shown in FIG. 1 will be described. FIG. 2 is a waveform diagram showing operation of the clock signal multiplying circuit shown in FIG. 1. By delaying the basic clock signal A shown in FIG. 2 by the buffers 1-9, a delay clock signal B_{H} is outputted from the buffer 9. At this point, a first power voltage is supplied to the buffers 1-9, and a delay time T_{H} in the buffers 1-9 is about ¼of a frequency A_{H} of the basic clock signal A.

As for the exclusive OR circuit 20, by obtaining an exclusive OR of the basic clock signal A and the delay clock signal B_{H}, a double multiplied clock signal C_{H} having a frequency double the clock signal is generated. At this point, duty of the double multiplied clock signal C_{H} is about 50%.

However, when operating this clock signal multiplying circuit under a second power voltage lower than the first power voltage, delay time in the buffer l-9 increases to T_{L} and a delay clock signal B_{L} shown in FIG. 2 is outputted from the buffer 9. In this case, the duty of the double multiplied clock signal C_{L} generated by the exclusive OR circuit 20 grows much larger than 50%, so that if the power voltage decreases more than this, it will make it impossible to carry out pulse separation accurately.

Accordingly, in this embodiment, by permitting the selector 10 to select a delay clock signal B_{C} outputted from the buffer 5, there is obtained a delay time T_{C} which is 5/9 times the delay time in the buffer 1-9. This enables the duty of a double multiplied clock signal C_{C} generated by the exclusive OR circuit 20 to approach 50%.

FIG. 3 is an exemplary circuit diagram showing a structural example of the control circuit shown in FIG. 1. As shown in FIG. 3, the control circuit 30 is constituted by a resistance 31 to an end of which a double multiplied clock signal is supplied, a capacitor 32 connected between the other end of the resistance 31 and a power voltage V_{SS} (to be an earth potential in this example), and a comparator 33. This control circuit 30 generates a control signal based on the duty of a double multiplied clock signal generated by the exclusive OR circuit 20.

Now, the comparator 33 has a hysteresis characteristic, comparing a detected potential V_{DET}, which is charged from the exclusive OR circuit 20 through the resistance 31 to the capacitor 32, to a reference potential V_{REF} and outputting a result of comparison as a control signal. It is to be noted that the double multiplied clock signal, when on high level, becomes a power potential V_{DD}, and, when on low level, becomes the earth potential V_{SS}. In this example, in a case where the duty of the double multiplied clock signal is 50%, a detected potential V becomes 0.5·(V_{DD}+V_{SS}).

If the duty of the double multiplied clock signal exceeds 50% and the detected potential V exceeds 0.7·(V_{DD}+V_{SS}), a control signal outputted from the comparator 33 takes on high level. Consequently, a delay clock signal outputted from the buffer 5 is selected by the selector 10, thus shortening delay time of the delay clock signal supplied by the exclusive OR circuit 20 to 5/9 times. This makes it possible to improve a follow-up ability relative to the basic clock signal of high frequency.

On the other hand, if the duty of the double multiplied clock signal falls below 30% and the detected potential V becomes less than 0.3·(V_{DD}+V_{SS}), the control signal outputted from the comparator 33 takes on low level. Consequently, a delay clock signal outputted from the buffer 9 is selected by the selector 10, thus extending the delay time of the delay clock signal supplied by the exclusive OR circuit 20 to 9/5 times. This makes it possible to improve a follow-up ability relative to the basic clock signal of low frequency.

By the way, in the control circuit 30 shown in FIG. 3, the resistance 31 may be substituted with a MOS transistor. Further, to prevent the comparison result of the comparator 33 from fluctuating due to an AC component of the double multiplied clock signal, integration capacity may be enhanced by setting up a higher order low-pass filter in place of a primary low-pass filter composed of the resistance 31 and the capacitor 32.

Next, a second embodiment according to this invention will be described.

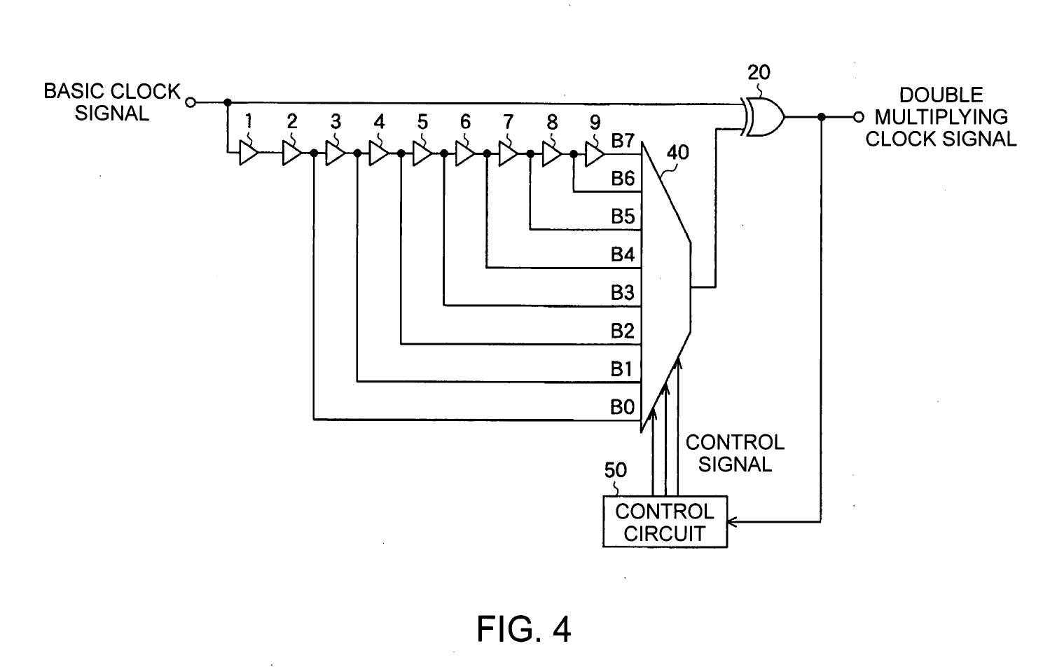

FIG. 4 is a diagram showing an exemplary construction of a clock signal double multiplying circuit incorporating a semiconductor integrated circuit according to a second embodiment of this invention. As shown in FIG. 4, this clock signal double multiplying circuit includes a plurality of buffers 1-9 connected in series to delay the basic clock signal in stages, a selector 40 to select one of the delay clock signals of eight kinds which have been provided with different delays in these buffers 1-9, the exclusive OR circuit 20 generating double multiplied clock signals having a frequency double the basic clock signal based on the delay clock signal selected by the basic clock signal and the selector 10, and a control circuit 50 controlling the selector 40.

The selector 40 selects one of delay clock signals B0-B7 respectively outputted from buffers 2-9 in accordance with a 3-bit control signal supplied from the control circuit 50. Or the selector 40 may select one of the delay clock signals B0-B7 in accordance with a 3-bit control signal supplied from a command parameter bus used for controlling the semiconductor integrated circuit as a whole.

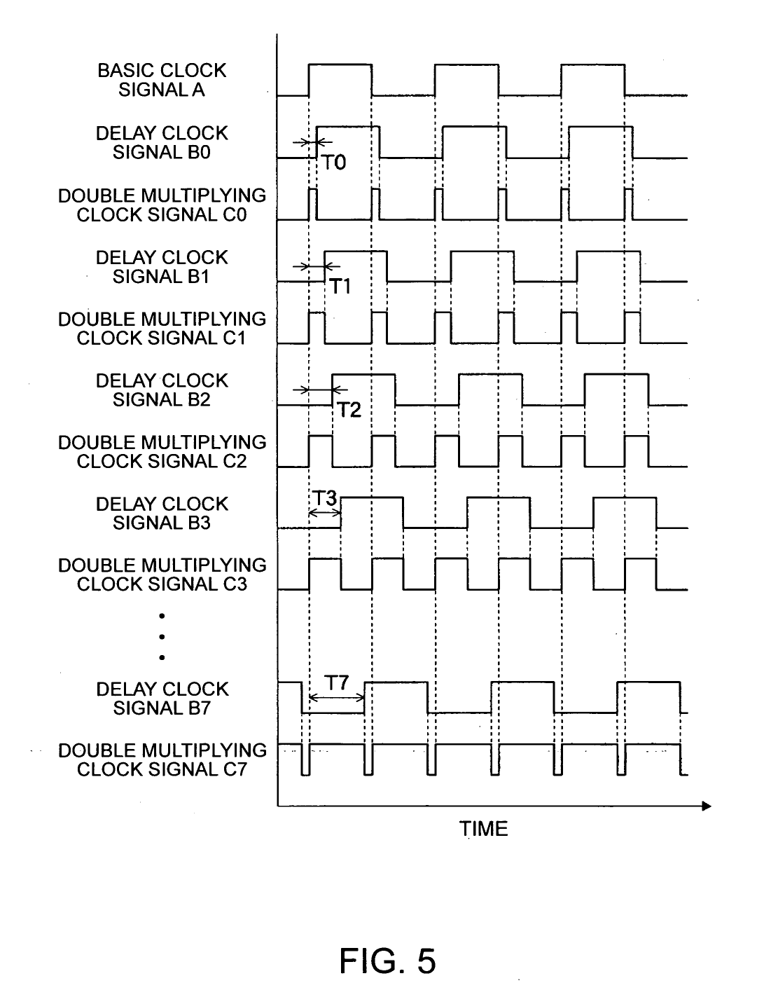

Now, referring to FIG. 4 and FIG. 5, operation of the clock signal multiplying circuit shown in FIG. 4 will be described. FIG. 5 is a waveform diagram showing operation of the clock signal multiplying circuit shown in FIG. 4. By delaying the basic clock signal A shown in FIG. 5 by the buffers 1-9, delay clock signals B0-B7 having respectively delay time T0-T7 relative to the basic clock signal A are supplied to the selector 40.

In the selector 40, one of these delay clock signals B0-B7 is selected and supplied to the exclusive OR circuit 20. The exclusive OR circuit 20, based on the delay clock signal selected by the basic clock signal A and the selector 40, generates a double multiplied clock signal having a frequency double the basic clock signal.

Now, the select circuit 50 can include the low-pass filter and the AD converter and generates the 3-bit control signal by performing AD conversion of an integration value obtained by integrating the double multiplied clock signal outputted from the exclusive OR circuit 20. As a result, there is generated a 3-bit control signal indicating in eight stages a value proportional to the duty of the double multiplied clock signal.

If a value shown by the control signal in the selector 40 is a minimum, a delay clock signal B7 having the maximum delay time is selected, whereby a negative feedback loop regarding the duty of the double multiplied clock signal is formed, maintaining the duty value approximately constant. Inasmuch as the double multiplied clock signals C0-C7 having a variety of duty may be selectively generated in this embodiment as shown in FIG. 5, it is possible to generate a double multiplied clock signal having a duty value close to constant relative to various power voltages and a frequency of the basic clock signal.

While the invention has been described in conjunction with specific embodiments thereof, it is evident that many alternatives, modifications and variations will be apparent to those skilled in the art. Accordingly, preferred embodiments of the invention as set forth herein are intended to be illustrative, not limiting. There are changes that may be made without departing from the spirit and scope of the invention.

What is claimed is:

1. A semiconductor integrated circuit, comprising:
a first circuit that delays a clock signal in stages;
a second circuit that selects one from a plurality of delay clock signals being provided with different delays in the first circuit; and
a third circuit that generates a double multiplied clock signal of which a frequency is doubled from of a frequency of the clock signal, based on a clock signal inputted to the first circuit and the delay clock signal selected by the second circuit.

2. 3The semiconductor integrated circuit according to claim 1, the first circuit further including a plurality of buffers coupled in series.

3. The semiconductor integrated circuit according to claim 1, the third circuit further including a circuit that generates the double multiplied clock signal of which a frequency is doubled from the frequency of the clock signal by obtaining an exclusive OR of the clock signal inputted to the first circuit and the delay clock signal selected by the second circuit.

4. The semiconductor integrated circuit according to claim 3, further comprising:
a control circuit that controls the second circuit based on a duty of the double multiplied clock signal generated by the third circuit.

5. The semiconductor integrated circuit according to claim 4, the control circuit further including:
a low-pass filter that integrates the double multiplied clock signal generated by the third circuit; and
a comparator or an AD converter that compares an output voltage of a low-pass filter with a reference voltage and outputs a comparative result obtained thereby as a control signal.

6. The semiconductor integrated circuit according to claim 5, the second circuit including a circuit that selects one of a plurality of delay clock signals respectively outputted by a prescribed buffer of the plurality of buffers in accordance with a control signal outputted by the control circuit.
